(19) United States
(12) Patent Application Publication
(10) Pub. No.: US 2004/0110365 A1
(43) Pub. Date: Jun. 10, 2004

(54) Method of forming a planarized bond pad structure

(75) Inventors: Yea-Zan Su, Hsin-Chu (TW); Cheng-Chung Huang, Jubei City (TW); Tien-Chi Wu, Yunghe City (TW); Kuo-Chou Chen, Tainan (TW)

Correspondence Address: GEORGE O. SAILE & ASSOCIATES, 28 DAVIS AVENUE, POUGHKEEPSIE, NY, 12603, US

(73) Assignee: Taiwan Semiconductor Manufacturing Company

(21) Appl. No.: 10/315,645

(22) Filed: Dec. 10, 2002

(51) Int. Cl. H01L 21/44

(52) U.S. Cl. 438/612

(57) ABSTRACT

A method of forming a planarized bond pad structure in a bond pad opening, while removing bond pad material from an opening in a non-device region used for scribe line formation, has been developed. A first iteration of this invention features the formation of the planarized bond bad structure in a bond pad opening defined in a dielectric layer, accomplished via deposition of a bond pad material followed by a chemical mechanical polishing (CMP), procedure, with the CMP procedure terminating at the top surface of the dielectric stop layer. The above procedures also result in unwanted bond pad material remaining in the scribe line opening. A photolithographic procedure defined to protect the planarized bond pad structure is used with a selective etching procedure removing unwanted bond pad material from the scribe line opening. A second iteration of this invention entails definition of a raised bond pad structure in the bond pad opening, accomplished via photolithographic and etch procedures, also resulting in removal of unwanted bond pad material from the scribe line opening. A subsequent CMP procedure results in the desired planarization of the bond pad structure.

### BACKGROUND OF THE INVENTION

(1) Field of the Invention

The present invention relates to methods used to fabricate semiconductor devices, and more specifically to a planarized bond pad structure employed to accommodate a subsequent wire bond design, and the method of forming the planarized bond pad structure.

(2) Description of Prior Art

Connection of semiconductor chips to external packaging component has been accomplished via employment of gold wires, one end bonded to a specific region of the semiconductor chip with the other end of the wire then connecting to the external component. The conductive region of the semiconductor chip used to accommodate the gold wire bond is a conductive bond pad structure, which in turn which communicates with the active device regions of a semiconductor substrate via multiple levels of metal interconnect structures. To improve the quality of the wire bonding procedure the quality of the conductive bond pad structure has to be maintained throughout pre-wire bond processes. For example after formation of a bond pad structure the semiconductor wafer is subjected to a backside grounding procedure used to thin the wafer to about 15 mils. Bond pad structures comprised of soft, aluminum based material, featuring raised top surface topographies are exposed to the grounding procedures and thus can be damaged in terms of scratches and breakage. In addition transporting semiconductor wafers after bond pad structure formation, to other areas of the semiconductor facility for dicing and bonding applications, can also result in bond pad damage. Damaged bond pad structure can adversely influence the quality of a gold wire bond in terms of increased resistance at the wire bond-bond pad structure interface, which in turn deleteriously influence the reliability and yield of a package comprised with individually wire bonded semiconductor chips.

This invention will describe a novel, planarized bond pad structure design, and a process sequence used to fabricate the planarized bond pad structure, in which a the top surface of the bond pad structure, in a bond pad opening, is maintained at the same level as the top surface of the dielectric layer in which the bond pad opening was defined in. This novel topographical situation removes the exposed top surface topography of the bond pad structure, thus offering protection to the bond pad structure during subsequent pre-dicing procedures such as wafer thinning and transportation. In addition this invention will combine the formation of the planarized bond pad structure with removal of bond pad material from scribe line regions, allowing subsequent dicing procedures to be performed in non-metallized scribe line regions. Prior art such as Ueno, in U.S. Pat. No. 5,696,406, Shih et al, in U.S. Pat. No. 6,361,704 B1, Gregoree et al, in U.S. Pat. No. 5,939,790, and Lee, in U.S. Pat. No. 6,084,312 B1, describe bonding pad structures and methods of forming these bond pad structures. None of the prior art however describe the present invention, a process sequence offering the combination of forming a planarized bonding pad structure in a silicon nitride defined opening, and removal of the conductive bond pad material from scribe line regions of the semiconductor wafer to be used for dicing procedures.

### SUMMARY OF THE INVENTION

It is an object of this invention to form a bond pad structure on a portion of a top surface of a metal level interconnect structure, exposed at the bottom of a bond pad opening.

It is another object of this invention to planarize the bond pad structure such that the top surface of the bond pad structure is equal to, or below the top surface of the dielectric layer in which the bond pad opening was defined in.

It is still another object of this invention to include with the formation of the planarized bond pad structure, a procedure to remove bond pad material from regions of the semiconductor wafer wherein dicing procedures will be performed.

In accordance with the present invention a method for forming a planarized bond pad structure in a bond pad opening defined in silicon nitride, and for removing bond pad material from regions to be used for dicing, is described. After defining a bond pad opening in a silicon nitride layer, exposing a portion of a top surface of a metal interconnect structure, and defining a scribe line opening in silicon nitride in a non-device region to be used for subsequent dicing procedures, a metal layer is deposited completely filling both the bond pad opening and the scribe line opening. A first iteration of this invention entails a chemical mechanical polishing (CMP), procedure selectively removing metal from the top surface of silicon nitride resulting in a planarized bond pad structure in the bond pad opening, with the top surface of the bond pad structure at the same level as the top surface of silicon nitride, or recessed below the silicon nitride layer as a result of a CMP dishing phenomena. The CMP procedure also results in unwanted metal in the scribe line opening. A photoresist shape is next used to protect the planarized bond pad structure during an etch procedure used to selectively remove the unwanted metal in the scribe line opening.

A second iteration of this invention again entails deposition of a metal layer filling both the bond pad opening and the scribe line opening. A photoresist shape is then used to allow removal of unwanted metal in the scribe line, as well as to allow definition of a raised, bond pad structure in the bond pad opening, to be realized. A CMP procedure is then employed to planarize the raised bond pad structure.

### BRIEF DESCRIPTION OF THE DRAWINGS

The object and other advantages of this invention are best described in the preferred embodiments with reference to the attached drawings that include:

FIGS. 1-5, which schematically in cross-sectional style describe a first iteration of this invention in which a CMP procedure, followed by photolithographic and etching procedures are employed to form a planarized bond pad structure in a bond pad opening, as well as to remove unwanted bond pad material from a scribe line opening.

FIGS. 6-8, which schematically in cross-sectional style describe a second iteration of this invention in which a photolithographic and etching procedures, followed by a CMP procedure, are used to remove unwanted bond pad material from a scribe line opening, as well as forming a planarized bond pad structure in a bond pad opening.

### DESCRIPTION OF THE PREFERRED EMBODIMENTS

The method of combining the formation of a planarized bond pad structure in a bond pad opening, and of removal of bond pad material from a scribe line opening, will now be described in detail. Region 1, indicated schematically in FIG. 1, will be used as the device region accommodating the subsequent bond pad structure while region 2, will be a non-device area, used for subsequent dicing procedures. Upper level interconnect structure 4, is shown overlying intermetal dielectric (IMD), layer 3, in device region 1. Although not shown in the drawings, upper level metal interconnect structure 4, in addition to overlying IMD layer 3, contacts lower level metal interconnect structures which in turn contact underlying active device regions in a semiconductor substrate. This is accomplished via use of metal plug structures (not shown in the drawings), formed in IMD layers located between underlying and overlying metal interconnect structures. IMD layer 3, overlying a lower level metal interconnect structures (not shown in the drawings), and accommodating the metal plug structure which allows contact and communication between metal interconnect structures, is comprised of a dielectric material such as silicon oxide, phosphosilicate glass (PSG), or boro-phosphosilicate glass (BPSG), each obtained via plasma enhanced chemical vapor deposition (PECVD), procedures, at a thickness between about 8,000 to 10,000 Angstroms. Upper level metal interconnect structure 4, comprised of a metal such as copper, is defined initiating with the deposition of a copper layer via plasma vapor deposition (PVD), procedures, at a thickness between about 6,000 to 12,000 Angstroms, followed by a chemical mechanical polishing (CMP), procedure.

After definition of upper level metal interconnect structure 4, via CMP procedures, dielectric layer 5, is deposited. Dielectric layer 5, is comprised of an insulator material that can perform as a stop layer for a subsequent CMP procedure. A material such as silicon nitride or silicon oxynitride is chosen for dielectric layer 5, either obtained via plasma enhanced chemical vapor deposition (PECVD), or low pressure chemical vapor deposition (LPCVD), procedures, at a thickness between about 9,000 to 12,000 Angstroms. If desired dielectric layer 5, can be a composite dielectric layer comprised of an underlying silicon oxide layer, obtained via PECVD or LPCVD procedures at a thickness between about 3,000 to 5,000 Angstroms, and an overlying silicon nitride or silicon oxynitride component, obtained via PECVD or LPCVD procedures at a thickness between about 5,000 to 7,000 Angstroms. Photolithographic and reactive ion etching (RIE), procedures, using SF₆/CF₄ as an etchant for dielectric layer 5, are next employed to define bond pad opening 6, in device region 1, exposing a portion of the top surface of upper level metal interconnect structure 4. The same photolithographic and RIE procedures also result in definition of scribe line opening 7, in non-device region 2. Scribe line opening 2, will be used as the area in which the subsequent dicing or sawing procedures will be performed in. The result of these procedures are schematically shown in FIG. 1.

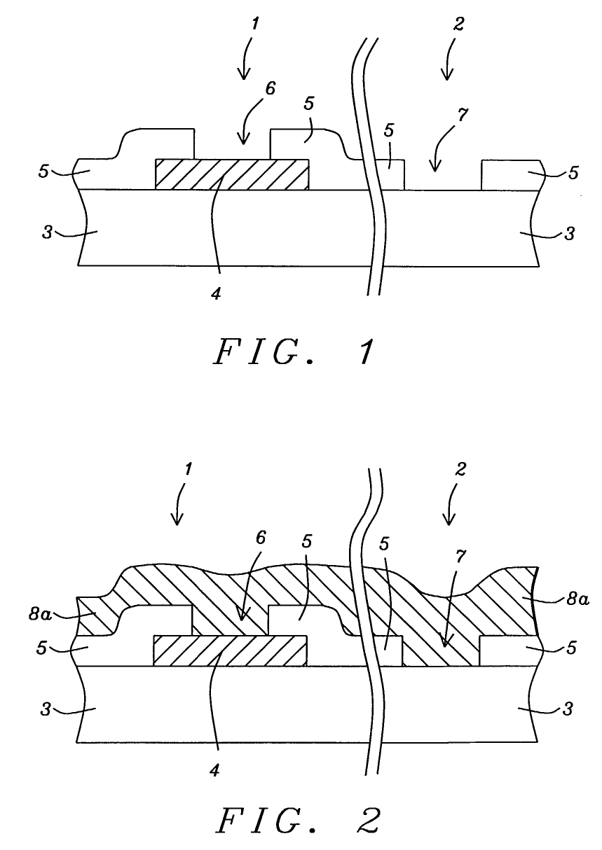

The photoresist shape used to define bond pad opening 6, and scribe line opening 7, is next removed via plasma oxygen ashing and wet clean procedures, with a buffered or dilute hydrofluoric acid step used as part of the wet clean procedure to remove native oxide from the portion of exposed top surface of upper metal interconnect structure 4. Metal layer 8a, comprised of an aluminum based material, is next deposited via plasma vapor deposition (PVD), procedures, to a thickness between about 10,000 to 14,000 Angstroms, completely filling bond pad opening 6, and scribe line opening 7. Aluminum based layer 8a, can be an aluminum-copper layer, comprised with a weight percent of copper between 0 to 2. The result of the metal deposition is schematically illustrated in FIG. 2.

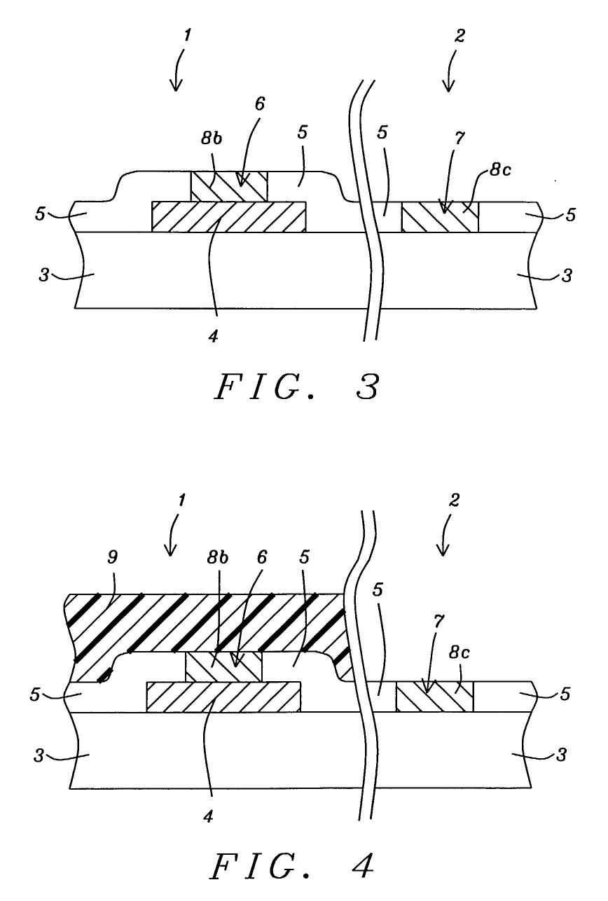

A first iteration of this invention featuring planarization of the bond pad structure, followed by removal of unwanted metal in scribe line opening 7, is next addressed and schematically described using FIGS. 3-5. A CMP procedure is used to selectively remove portions of metal layer 8a, from the top surface of dielectric or stop layer 5. The result of the selective CMP procedure is the desired, planarized bond pad structure 8b, in bond pad opening 6, and the undesired metal portion 8c, in scribe line opening 7. This is schematically shown in FIG. 3. Additional CMP processing performed after the appearance of dielectric stop layer 5, can result in a dishing phenomena, wherein the top surface of planarized bond pad structure 8b, is lower than the top surface of dielectric layer 5. However in either case, wherein the top surface of planarized bond pad structure is at the same level as, or below the level of the top surface of dielectric layer 5, the damage to the soft bond pad structure will be reduced during subsequent processes, when compared to counterpart bond pad structures in which a raised topography, or wherein the top surface of the bond pad structure was the highest feature of the semiconductor chip.

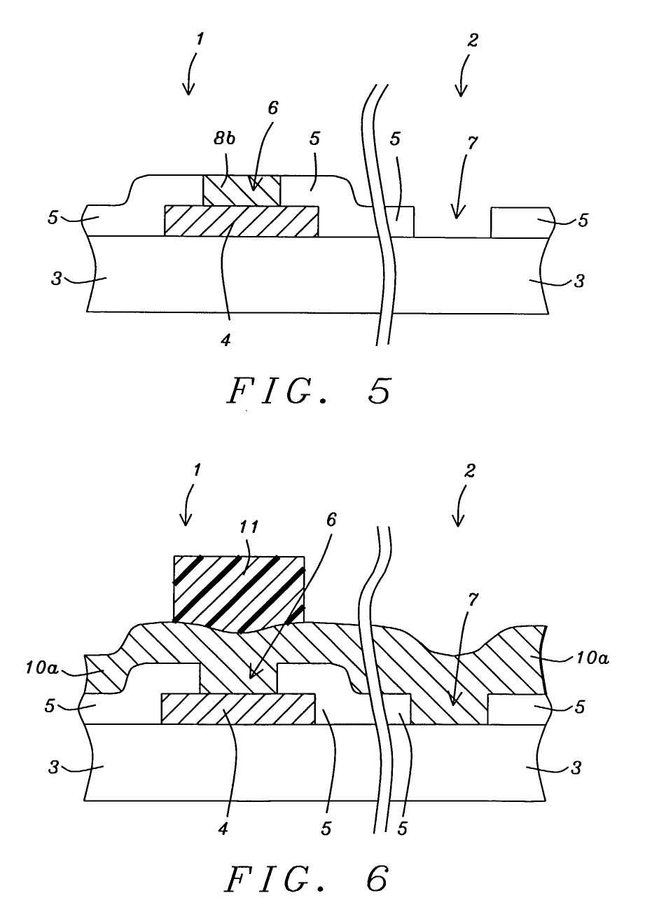

The presence of metal portion 8c, in scribe line opening 7, will interfere with subsequent dicing operations. The apparatus or saw used to dice, or separate individual semiconductor chips, can be damaged by cutting through the soft metal portion 8c. Therefore removal of metal portion 8c, is next addressed. Photoresist shape 9, schematically shown in FIG. 4, is formed in device region 1, protecting planarized bond pad structure 8b, from either a wet or dry etch procedure used to remove metal portion 8c, from scribe line opening 2. A selective RIE procedure is performed using Cl₂ as an etchant for metal portion 8c. A wet etch option can be employed, using a solution of CH₃COOH/HNO₃ as a selective etchant for metal portion 8c. Removal of photoresist shape 9, via plasma oxygen ashing and wet clean procedures, result in planarized bond pad structure 8b, in bond pad opening 6, and scribe line opening 7, now free of metal. The result of these procedures is schematically illustrated in FIG. 5.

A second iteration of this invention featuring a first procedure of defining a raised bond pad structure and removal of unwanted metal in scribe line opening 7, followed by a second procedure in which a CMP procedure is used to planarize the raised bond pad structure, is next addressed and schematically described using FIGS. 6-8. Metal layer 10a, is deposited via PVD procedures to a thickness between about 10,000 to 14,000 Angstroms, again completely filling bond pad opening 6, and scribe line opening 7. Metal layer 10a, again can be an aluminum based layer such as an aluminum-copper layer, featuring a weight percent of copper between about 0 to 2. Photoresist shape 11, shown schematically in FIG. 6, is next formed on the portion of metal layer 10a, located in bond pad opening 6. Other portions of metal layer 10a, in device region 1, and all portions of metal layer 10a, in non-device region 2, are not covered by photoresist shape 11.

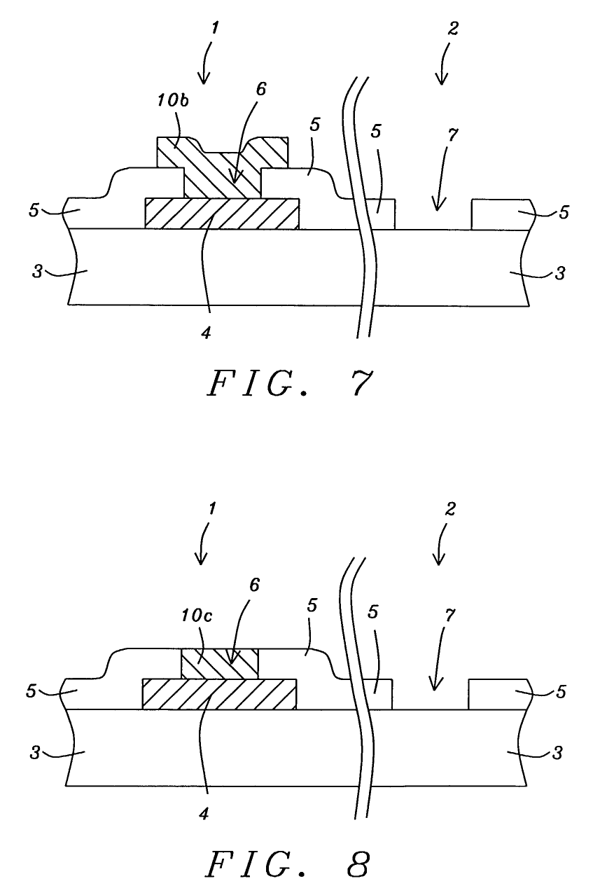

Removal of exposed portions of metal layer 10a, is next accomplished via a RIE procedure, performed using Cl₂ as a selective etchant for metal layer 10a. The RIE procedure results in definition of raised bond pad structure 10b, in bond pad opening 6, in device region 1, while the desired result of complete removal of metal layer 10a, in scribe line opening 7, has been realized. This is schematically shown in FIG. 7, after removal of photoresist shape 11, accomplished via plasma oxygen ashing procedures. If desired the portions of metal layer 10a, not protected by photoresist shape 11, can be selectively removed via wet etch procedures, using CH₃COOH/HNO₃ as an etchant for metal layer 10a.

The desired result of obtaining a planarized bond pad structure, a structure that will feature a top surface equal to, or lower than the top surface of dielectric layer 5, is next addressed. A CMP procedure is again employed, selectively removing metal and terminating at the appearance of dielectric or stop layer 5. The removal of the top portion of raised bond pad structure 10b, via the CMP procedure, results in the desired, planarized bond pad structure 10c, located entirely in bond pad opening 6. If desired additional CMP processing can be performed after attainment of planarized bond pad structure 10c, resulting in a dished bond pad structure, with the top surface of the bond pad structure now below the top surface of dielectric layer 5. Both iterations of this invention result in a planarized bond structure, as well as absence of metal in scribe line openings.

While this invention has been particularly shown and described with reference to, the preferred embodiments thereof, it will be understood by those skilled in the art that various changes in form and details may be made without departing from the spirit and scope of this invention.

What is claimed is:

1. A method of forming a bad pond structure on a semiconductor substrate, comprising the steps of:
forming an upper level metal interconnect structure, with said upper level metal interconnect structure communicating with active device regions in said semiconductor substrate;
forming a first opening in a dielectric layer exposing a portion of a top surface of said upper level metal interconnect structure, and forming a second opening in said dielectric layer exposing an underlying portion of said semiconductor substrate located in a non-device region;
depositing a metal layer completely filling said first opening, and said second opening;
performing a chemical mechanical polishing procedure forming a planarized bond pad structure in said first opening, and forming a metal structure in said second opening; and
removing said metal structure from said second opening.

2. The method of claim 1, wherein said upper level metal interconnect structure is comprised of copper.

3. The method of claim 1, wherein said dielectric layer is a silicon nitride layer, obtained via plasma enhanced chemical vapor deposition (PECVD), or via low pressure chemical vapor deposition (LPCVD), procedures, at a thickness between about 9,000 to 12,000 Angstroms.

4. The method of claim 1, wherein said dielectric layer is a silicon oxynitride layer, obtained via PECVD or via LPCVD, procedures, at a thickness between about 9,000 to 12,000 Angstroms.

5. The method of claim 1, wherein said dielectric layer is a composite dielectric layer, comprised of an underlying silicon oxide layer, obtained via PECVD or LPCVD procedures at a thickness between about 3,000 to 5,000 Angstroms, and comprised of an overlying silicon nitride or silicon oxynitride layer, obtained via PECVD or LPCVD procedures at a thickness between about 5,000 to 7,000 Angstroms.

6. The method of claim 1, wherein said first opening, and said second opening, are formed in said dielectric layer via a reactive ion etching (RIE), procedure, using SF₆/CF₄ as an etchant for said dielectric layer.

7. The method of claim 1, wherein said metal layer is an aluminum-copper layer, obtained via plasma vapor deposition procedures at a thickness between about 10,000 to 14,000 Angstroms, comprised with a weight percent of copper between about 0 to 2.

8. The method of claim 1, wherein said metal structure is removed from said second opening via a RIE procedure, using Cl₂ as an etchant.

9. The method of claim 1, wherein said metal structure is removed from said second opening via a wet etch procedure, using CH₃COOH/HNO₃ as an etchant.

10. A method of forming a planarized bond pad structure in a bond pad opening located in a device region of a semiconductor substrate, while removing bond pad structure material from a scribe line opening located in a non-device region of said semiconductor substrate, comprising the steps of:
providing a lower level metal interconnect structure contacting active device regions in said semiconductor substrate, with an intermetal dielectric (IMD), layer located on the top surface of said lower level interconnect structure;
forming an upper level metal interconnect structure on said IMD layer, with said upper level metal interconnect structure communicating with said lower level metal interconnect structure via a metal plug structure located in said IMD layer;
depositing a dielectric layer;
forming a bond pad opening in said dielectric layer exposing a portion of a top surface of said upper level metal interconnect structure in said device region of said semiconductor substrate, and forming a scribe line opening in said dielectric layer, in said non-device region;
depositing an aluminum based layer completely filling said bond pad opening and said scribe line opening;
performing a patterning procedure to define a non-planarized bond pad structure in said bond pad opening, with said non-planarized bond pad structure featuring a raised top surface topography, and with said patterning procedure removing portion of said aluminum based layer from said scribe line opening, and
performing a chemical mechanical polishing procedure removing raised portion of said non-planarized bond pad structure, resulting in said planarized bond pad structure.

11. The method of claim 10, wherein said IMD layer is comprised of silicon oxide, boro-phosphosilicate glass, or phosphosilicate glass.

12. The method of claim 10, wherein said upper level metal interconnect structure is comprised of copper.

13. The method of claim 10, wherein said dielectric layer is a silicon nitride layer, obtained via plasma enhanced chemical vapor deposition (PECVD), or via low pressure chemical vapor deposition (LPCVD), procedures, at a thickness between about 9,000 to 12,000 Angstroms.

14. The method of claim 10, wherein said dielectric layer is a silicon oxynitride layer, obtained via PECVD or via LPCVD, procedures, at a thickness between about 9,000 to 12,000 Angstroms.

15. The method of claim 10, wherein said dielectric layer is a composite dielectric layer, comprised of an underlying silicon oxide layer, obtained via PECVD or LPCVD procedures at a thickness between about 3,000 to 5,000 Angstroms, and comprised of an overlying silicon nitride or silicon oxynitride layer, obtained via PECVD or LPCVD procedures at a thickness between about 5,000 to 7,000 Angstroms.

16. The method of claim 10, wherein said bond pad opening and said scribe line opening, are formed in said dielectric layer via a reactive ion etching (RIE), procedure, using SF₆/CF₄ as an etchant for said dielectric layer.

17. The method of claim 10, wherein said aluminum based layer is an aluminum-copper layer, obtained via plasma vapor deposition procedures at a thickness between about 10,000 to 14,000 Angstroms, comprised with a weight percent of copper between about 0 to 2.

19. The method of claim 10, wherein said patterning procedure used to define said non-planarized bond pad structure, and used to remove portion of said aluminum based layer from said scribe line, is a RIE procedure, performed using Cl₂ as an etchant.

20. The method of claim 10, wherein said patterning procedure used to define said non-planarized bond pad structure, and used to remove portion of said aluminum based layer from said scribe line, is a wet etch procedure, performed using CH₃COOH/HNO₃ as an etchant.

21. A planarized bond pad structure on a semiconductor substrate, comprising:
a first region of said semiconductor substrate used as an active device region, and a second region of said semiconductor substrate used as an non-device, scribe line region of said semiconductor substrate;
a metal interconnect structure located in said first region of said semiconductor substrate, contacting active device regions in said semiconductor substrate, or with said metal interconnect structure contacting a lower level metal structure wherein said lower level metal structure in turn contacts said active device regions in said semiconductor substrate;
a bond pad opening in a dielectric layer located in said first region of said semiconductor substrate, exposing a portion of top surface of said metal interconnect structure;
a scribe line opening in said dielectric layer, located in said second region of said semiconductor substrate; and
said planarized bond pad structure located entirely in said bond pad opening, contacting a portion of said metal interconnect structure exposed at bottom of said bond pad opening, featuring a top surface of said bond pad structure equal to the top surface of said dielectric layer.

22. The planarized bond pad structure of claim 21, wherein said metal interconnect structure is comprised of copper.

23. The planarized bond pad structure of claim 21, wherein said dielectric layer is comprised of silicon nitride, at a thickness between about 9,000 to 12,000 Angstroms.

24. The planarized bond pad structure of claim 21, wherein said dielectric layer is comprised of silicon oxynitride, at a thickness between about 9,000 to 12,000 Angstroms.

25. The planarized bond pad structure of claim 21, wherein said dielectric layer is a composite dielectric layer, comprised of an underlying layer of silicon oxide at a thickness between about 3,000 to 5,000 Angstroms, and comprised of an overlying layer of silicon nitride, or silicon oxynitride, at a thickness between about 5,000 to 7,000 Angstroms.

26. The planarized bond pad structure of claim 21, wherein said planarized bond pad structure is comprised of an aluminum based layer, such as an aluminum-copper layer, with a weight percent of copper between about 0 to 2.

27. The method of claim 21, wherein said planarized bond pad structure is comprised at a thickness between about 10,000 to 14,000 Angstroms.
